(19) United States
(12) Patent Application Publication
(10) Pub. No.: US 2024/0136193 A1
(43) Pub. Date: Apr. 25, 2024

(54) METHOD OF PROCESSING WAFER

(71) Applicant: DISCO CORPORATION, Tokyo (JP)

(72) Inventors: Kai MINAMIZAKI, Tokyo (JP); Shunsuke TERANISHI, Tokyo (JP); Akira MIZUTANI, Tokyo (JP)

(21) Appl. No.: 18/479,948

(22) Filed: Oct. 2, 2023

(30) Foreign Application Priority Data
Oct. 24, 2022 (JP) 2022-170539

(51) Int. Cl. H01L 21/304; H01L 23/00; H10B 80/00

(52) U.S. Cl. CPC H01L 21/304; H01L 24/80; H01L 24/94; H10B 80/00; H01L 2224/80013; H01L 2224/8023; H01L 2224/80894; H01L 2224/80948; H01L 2224/94

(57) ABSTRACT

A method of processing a wafer includes a plasma activation processing step of performing plasma processing on at least either one surface of a first wafer or one surface of a second wafer to activate the surface, a bonded wafer forming step of forming a bonded wafer by provisionally joining the first wafer and the second wafer, a modified layer forming step of forming modified layers in an annular pattern inside the first wafer by applying a laser beam of a wavelength having transmissivity for the first wafer, an outer peripheral region removal step of removing an outer peripheral region of the first wafer by applying an external force, an anneal processing step of performing anneal processing to increase joint strength of the bonded wafer, and a grinding step of grinding the first wafer to thin it to a finish thickness.

### BACKGROUND OF THE INVENTION

### Field of the Invention

The present invention relates to a method of processing a wafer.

### Description of the Related Art

Keeping in step with the move toward low-profile and high-integration device chips in recent years, development of three-dimensionally stacked semiconductor wafers is under progress. For example, a through-silicon via (TSV) wafer makes it possible to connect electrodes of two chips to each other by bonding both the chips together with through electrodes.

Such a wafer is thinned by being ground in a state of being bonded to a support wafer which is made of silicon (Si), glass, ceramics, or the like as a substrate. In general, a wafer is chamfered at an outer peripheral edge thereof. When the wafer is ground extremely thin, the outer peripheral edge is thus formed into what is called a knife edge, so that edge chipping is prone to occur during grinding. There is hence a possibility that the chipping may extend to devices and lead to damage to the devices.

As a measure for a knife edge, what is called an edge trimming technique has been developed to cut an outer peripheral edge of a wafer in an annular profile on a side of a front surface thereof (see JP 4895594B). In addition, an edge trimming method has also been contrived. According to this edge trimming method, a first wafer which has a device region with devices formed therein and a second wafer are bonded together, and a laser beam is then applied to the first wafer along an outer peripheral edge of the device region to form modified layers in an annular pattern inside the first wafer, thereby suppressing the edge chipping, which occurs during grinding of the first wafer, from spreading to the devices (see JP 2020-057709A).

### SUMMARY OF THE INVENTION

However, the method of JP 4895594B has a possibility of causing chipping to occur to such an extent as to reach devices and damaging the devices during grinding, and also involves a problem that the devices are prone to contamination with contaminants due to production of a great deal of grinding debris. Further, the method of JP 2020-057709A has a possibility of causing an edge material of an outer peripheral surplus region, which is to be removed at the time of the grinding, to remain unremoved without separation if the modified layers are formed on a side inner than a joined region between the first wafer and the second wafer.

The present invention therefore has, as objects thereof, the provision of methods of processing a wafer which can remove such an outer peripheral surplus region while suppressing damage to devices in a step of grinding a bonded wafer.

In accordance with an aspect of the present invention, there is provided a method of processing a wafer which includes a plasma activation processing step of performing plasma processing on at least either one surface of a first wafer or one surface of a second wafer and thus activating the at least one surface that has been subjected to the plasma processing, to thereby join the first wafer and the second wafer, a bonded wafer forming step of, after performing the plasma activation processing step, forming a bonded wafer by provisionally joining the one surface of the first wafer and the one surface of the second wafer, a modified layer forming step of, after performing the bonded wafer forming step, forming modified layers in an annular pattern inside the first wafer by applying a laser beam of a wavelength having transmissivity for the first wafer, in the annular pattern to the first wafer along a position on a side inner by a predetermined distance than an outer peripheral edge of the first wafer, an outer peripheral region removal step of, after performing the modified layer forming step, removing an outer peripheral region of the first wafer, the outer peripheral region being on a side of the outer peripheral edge relative to the position where the modified layers have been formed in the annular pattern, by applying an external force to the outer peripheral region, an anneal processing step of, after performing the outer peripheral region removal step, performing anneal processing on the bonded wafer to increase joint strength between the first wafer and the second wafer, and a grinding step of, after performing the anneal processing step, grinding the first wafer of the bonded wafer from another surface of the first wafer to thin the first wafer to a predetermined finish thickness.

In accordance with another aspect of the present invention, there is provided a processing method of processing a wafer which includes a plasma activation processing step of performing plasma processing on at least either one surface of a first wafer or one surface of a second wafer and thus activating the at least one surface that has been subjected to the plasma processing, to thereby join the first wafer and the second wafer, a bonded wafer forming step of, after performing the plasma activation processing step, forming a bonded wafer by provisionally joining the one surface of the first wafer and the one surface of the second wafer, a modified layer forming step of, after performing the bonded wafer forming step, forming modified layers in an annular pattern inside the first wafer and also forming cracks in such a manner as to spread from the modified layers and appear on the one surface of the first wafer, by applying a laser beam of a wavelength having transmissivity for the first wafer, in the annular pattern to the first wafer along a position on a side inner by a predetermined distance than an outer peripheral edge of the first wafer, an anneal processing step of, after performing the modified layer forming step, performing anneal processing on the bonded wafer to increase joint strength between the first wafer and the second wafer, an outer peripheral region removal step of, after performing the anneal processing step, removing an outer peripheral region of the first wafer, the outer peripheral region being on a side of the outer peripheral edge relative to the position where the modified layers have been formed in the annular pattern, by applying an external force to the outer peripheral region, and a grinding step of, after performing the outer peripheral region removal step, grinding the first wafer of the bonded wafer from another surface of the first wafer to thin the first wafer to a predetermined finish thickness.

Preferably, in the modified layer forming step, the laser beam may be applied a plurality of times to the first wafer with a height position of a focal point of the laser beam changed every time in a thickness direction of the first wafer, such that modified layers are formed in a like plurality of annular patterns overlapping in the thickness direction of the first wafer.

Also preferably, in the modified layer forming step, a laser beam having a plurality of focal points apart from one another in a thickness direction of the first wafer may be applied to the first wafer such that modified layers are formed in a like plurality of annular patterns overlapping in the thickness direction of the first wafer.

The present invention can remove the outer peripheral surplus region while suppressing damage to the devices in the step of grinding the bonded wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a wafer to which a method of processing a wafer according to an embodiment of the present invention is to be applied;

FIG. 2 is a fragmentary cross-sectional view taken along line II-II illustrated in FIG. 1;

FIG. 3 is a flow chart illustrating a flow of the method of processing a wafer according to the embodiment;

FIG. 4 is a partly cross-sectional side view illustrating an example of a plasma activation processing step illustrated in FIG. 3;

FIG. 5 is a perspective view illustrating how a bonded wafer forming step illustrated in FIG. 3 is performed;

FIG. 6 is a fragmentary cross-sectional view schematically illustrating the details of bonding between joined surfaces in a bonded wafer produced by the bonded wafer forming step illustrated in FIG. 3;

FIG. 7 is a partly cross-sectional side view illustrating how a modified layer forming step illustrated in FIG. 3 is performed;

FIG. 8 is a plan view illustrating the bonded wafer that has undergone the modified layer forming step illustrated in FIG. 3;

FIG. 9 is a partly cross-sectional side view illustrating an example of an outer peripheral region removal step illustrated in FIG. 3;

FIG. 10 is a partly cross-sectional side view illustrating an example of an anneal processing step illustrated in FIG. 3;

FIG. 11 is a fragmentary cross-sectional view schematically illustrating the details of bonding between the joined surfaces in the bonded wafer that has undergone the anneal processing step illustrated in FIG. 3;

FIG. 12 is a partly cross-sectional side view illustrating how a grinding step illustrated in FIG. 3 is performed; and

FIG. 13 is a fragmentary cross-sectional view illustrating, on an enlarged scale, a portion of a bonded wafer that has undergone a modified layer forming step in a method of processing a wafer according to a modification of the embodiment.

### DETAILED DESCRIPTION OF THE PREFERRED EMBODIMENT

With reference to the attached drawings, an embodiment of the present invention and a modification of the embodiment will hereinafter be described in detail. However, the present invention shall not be limited to the details of the following embodiment and modification. The elements of configurations that will hereinafter be described include those readily conceivable to persons skilled in the art and those substantially the same as ones described below. Further, the configurations that will hereinafter be described can be combined appropriately. Moreover, various omissions, replacements, and modifications of configurations can be made without departing from the spirit of the present invention.

### Embodiment

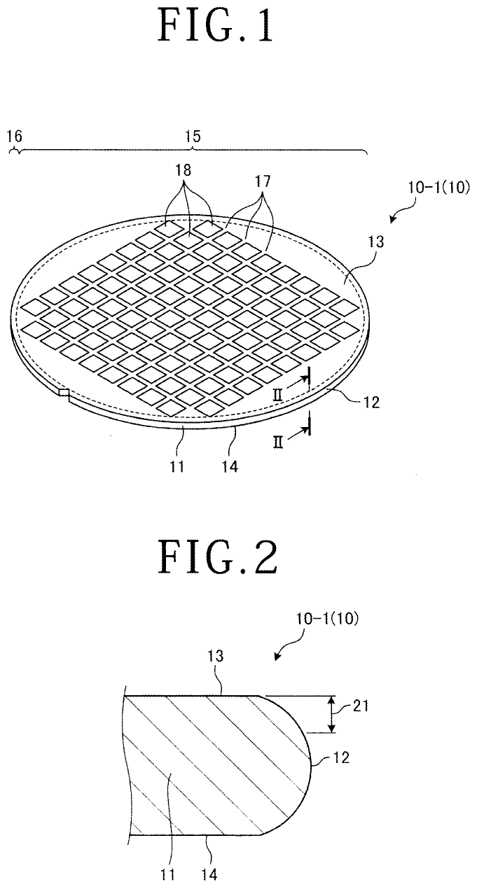

A method of processing a wafer 10 according to the embodiment of the present invention will be described based on FIGS. 1 to 12. FIG. 1 is a perspective view illustrating an example of the wafer 10 to which the method of processing a wafer according to the present embodiment is to be applied. FIG. 2 is a fragmentary cross-sectional view taken along line II-II illustrated in FIG. 1.

The wafer 10 illustrated in FIGS. 1 and 2 is such a wafer as a disk-shaped semiconductor wafer or optical device that uses Si, sapphire (Al₂O₃), gallium arsenide (GaAs), silicon carbide (SiC), or the like for a substrate 11, and is an Si wafer in the present embodiment. As illustrated in FIG. 2, the wafer 10 is chamfered at an outer peripheral edge 12 thereof such that the wafer 10 protrudes most toward an outer periphery at the center in a thickness direction thereof and has a round arc profile in cross-section from a front surface 13 to a back surface 14 of the substrate 11.

As illustrated in FIG. 1, the wafer 10 includes, on the front surface 13 of the substrate 11, a central region 15 and an outer peripheral region 16 surrounding the central region 15. The central region 15 has a plurality of division lines 17 set in a grid pattern on the front surface 13 of the substrate 11 and devices 18 formed in respective regions defined by the division lines 17. The outer peripheral region 16 surrounds the central region 15 over the entirety of a periphery thereof and has no devices 18 formed therein.

In the present embodiment, the devices 18 constitute three dimensional NOT-AND (3D NAND) flash memories and include electrode pads and through electrodes connected to the electrode pads. When the substrate 11 is thinned and the devices 18 are individually divided from the wafer 10, the through electrodes extend to the back surface 14 of the substrate 11. The wafer 10 in the present embodiment is thus what is called a TSV wafer in which the individually formed devices 18 each have through electrodes. However, it is to be noted that the wafer 10 in the present invention is not limited to such a TSV wafer having through electrodes as in the present embodiment and may be a device wafer having no through electrodes.

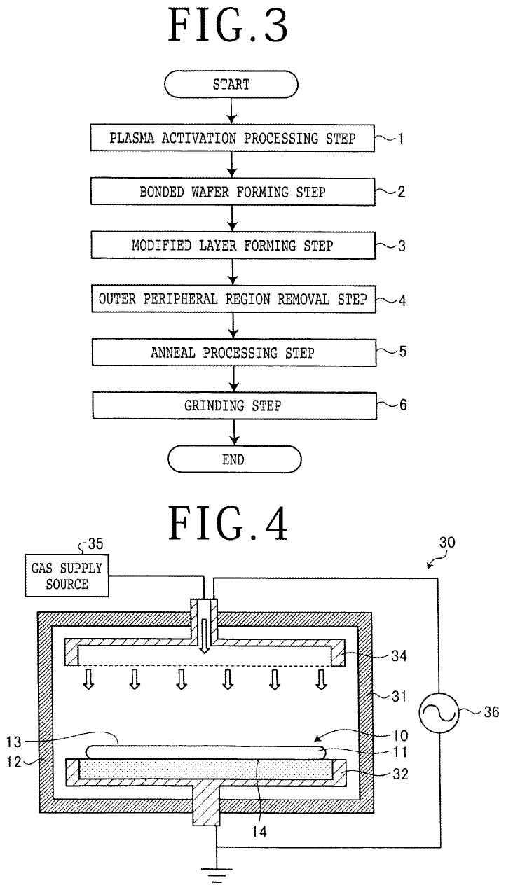

FIG. 3 is a flow chart illustrating a flow of the method of processing the wafer 10 according to the embodiment. As illustrated in FIG. 3, the method of processing the wafer 10 according to the present embodiment includes a plasma activation processing step 1, a bonded wafer forming step 2, a modified layer forming step 3, an outer peripheral region removal step 4, an anneal processing step 5, and a grinding step 6. The method of processing the wafer 10 according to the present embodiment is a method of bonding one surfaces of a pair of wafers 10 together and thinning one of the wafers 10 (first wafer 10-1) to a predetermined finish thickness 21 (see FIG. 2). It is to be noted that, in the present embodiment, the one surfaces are the front surfaces 13.

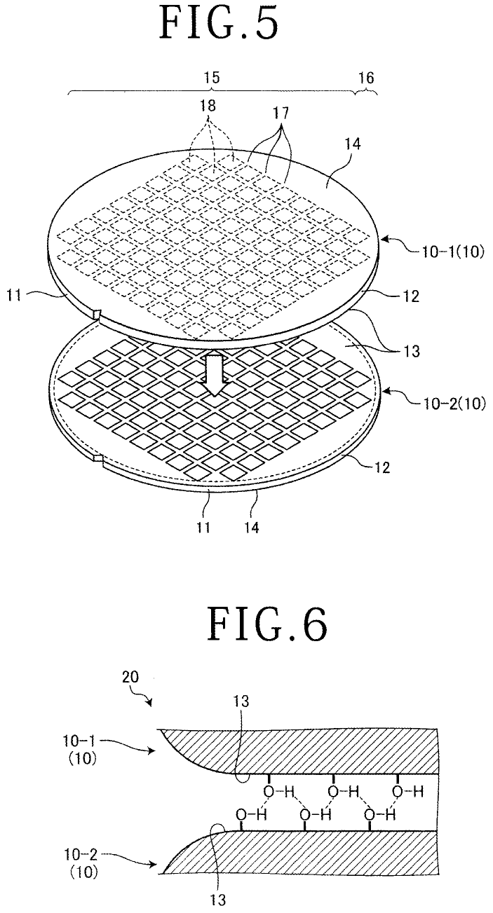

It is to be noted that, when the pair of wafers 10 are distinguished from each other in the following description, one wafer 10 will be referred to as the “first wafer 10-1,” and the other wafer 10 will be referred to as a “second wafer 10-2” (see FIG. 5). When the wafers 10 are not distinguished from each other, they will simply be referred to as the “wafers 10.” The other wafer 10, i.e., the second wafer 10-2, that will not be thinned will be described as a TSV wafer similar to the first wafer 10-1 in the present embodiment, but may also be a simple substrate wafer having no pattern in the present invention.

FIG. 4 is a partly cross-sectional side view illustrating an example of the plasma activation processing step 1 illustrated in FIG. 3. To join the first wafer 10-1 and the second wafer 10-2 together, the plasma activation processing step 1 performs plasma processing on each surface to be joined, whereby the surface to which the plasma processing is performed is activated. In the plasma activation processing step 1, the plasma processing is performed on at least either the one surface of the first wafer 10-1 or the one surface of the second wafer 10-2.

In the plasma activation processing step 1 according to the present embodiment, the plasma processing is performed on the front surface 13 of each of the wafers 10 (first wafer 10-1 and second wafer 10-2) in a plasma processing system 30 illustrated in FIG. 4. The plasma processing system 30 includes a chamber 31, a lower electrode 32, an upper electrode 34, a gas supply source 35, and a radio frequency power supply 36, and also includes an electrostatic attraction system, a lift mechanism, a loading/unloading opening, and an exhaust system, which are not illustrated.

In the chamber 31, the lower electrode 32 and the upper electrode 34 are arranged to vertically face each other. The lower electrode 32 is formed of an electrically conductive material and has a disk-shaped holding portion for holding the wafer 10. Inside the holding portion, the electrostatic attraction system, which is not illustrated, is formed. When the electrostatic attraction system is energized, the wafer 10 placed on an upper surface of the holding portion can be fixed by electrostatic attraction.

The upper electrode 34 is formed of an electrically conductive material and has a disk-shaped gas ejection portion that covers above the wafer 10 held on the holding portion of the lower electrode 32. The gas ejection portion is in communication with the gas supply source 35. The gas supply source 35 supplies a process gas such as argon (Ar), nitrogen (N₂), or oxygen (O₂) into the chamber 31 through the gas ejection portion. The upper electrode 34 is movable up and down relative to the lower electrode 32 by the lift mechanism, which is not illustrated.

The lower electrode 32 and the upper electrode 34 have respective insulating members, which are not illustrated, between themselves and a bottom wall and top wall of the chamber 31 and are isolated from the chamber 31. The lower electrode 32 and the upper electrode 34 are connected to the radio frequency power supply 36. Based on control signals outputted from a controller not illustrated, the radio frequency power supply 36 supplies predetermined radio frequency power to the lower electrode 32 and the upper electrode 34.

In the plasma activation processing step 1, the wafer 10 is first loaded into the chamber 31 from the loading/unloading opening, which is not illustrated, and is placed on the holding portion of the lower electrode 32 such that the front surface 13 of the wafer 10 is directed upward. The electrostatic attraction system, which is not illustrated, is then activated, so that the wafer 10 is electrostatically attracted and held on the holding portion. Further, the loading/unloading opening, which is not illustrated, is closed, so that a processing space in the chamber 31 is hermetically closed. Moreover, the height position of the upper electrode 34 is adjusted by the lift mechanism, which is not illustrated, such that the lower electrode 32 and the upper electrode 34 are brought into a predetermined positional relation suited for the plasma processing.

In the plasma activation processing step 1, the exhaust system, which is not illustrated, is next driven to bring the processing space in the chamber 31 to vacuum (low pressure). While the process gas is supplied at a predetermined flow rate from the gas supply source 35 to the processing space in the chamber 31, the predetermined radio frequency power is then supplied from the radio frequency power supply 36 to the lower electrode 32 and the upper electrode 34, so that a plasma state gas is supplied to the front surface 13 of the wafer 10. By performing such plasma processing, surface impurities such as organic matter adsorbed on the front surface 13 of the wafer 10 are removed, and a clean surface is exposed. Further, hydroxyl groups (OH groups) are bound to Si dangling bonds on the exposed, clean front surface 13. In other words, OH groups are formed on the front surface 13 of the wafer 10 which has been activated by the plasma processing.

The plasma activation processing step 1 according to the present embodiment is performed on both the front surface 13 of the first wafer 10-1 and the front surface 13 of the second wafer 10-2 but may be performed on only one of these surfaces.

FIG. 5 is a perspective view illustrating how the bonded wafer forming step 2 illustrated in FIG. 3 is performed. FIG. 6 is a fragmentary cross-sectional view schematically illustrating the details of bonding between joined surfaces in a bonded wafer 20 produced by the bonded wafer forming step 2 illustrated in FIG. 3. The bonded wafer forming step 2 is performed after the plasma activation processing step 1 is performed. The bonded wafer forming step 2 forms the bonded wafer 20 by provisionally joining the first wafer 10-1 and the second wafer 10-2 together.

In the bonded wafer forming step 2, at least one surface on which OH groups have been formed in the plasma activation processing step 1 is used as a surface to be joined. In the present embodiment, the front surface 13 of the first wafer 10-1 and the front surface 13 of the second wafer 10-2 are bonded together.

In the bonded wafer forming step 2, the front surface 13 of the first wafer 10-1 and the front surface 13 of the second wafer 10-2 are first brought to face each other with an interval left therebetween. The front surface 13 of the first wafer 10-1 and the front surface 13 of the second wafer 10-2 are then bonded together. Consequently, the bonded wafer 20 is formed.

On this occasion, the hydrogen atoms (H) of OH groups formed on the front surface 13 of the first wafer 10-1 form non-covalent hydrogen bonds with the oxygen atoms (O) of OH groups formed on the front surface 13 of the second wafer 10-2. In parallel with the foregoing, the hydrogen atoms (H) of the OH groups formed on the front surface 13 of the second wafer 10-2 also form non-covalent hydrogen bonds with the oxygen atoms (O) of the OH groups formed on the front surface 13 of the first wafer 10-1. Consequently, the first wafer 10-1 and the second wafer 10-2 are attracted to each other through the hydrogen bonds and are provisionally joined together.

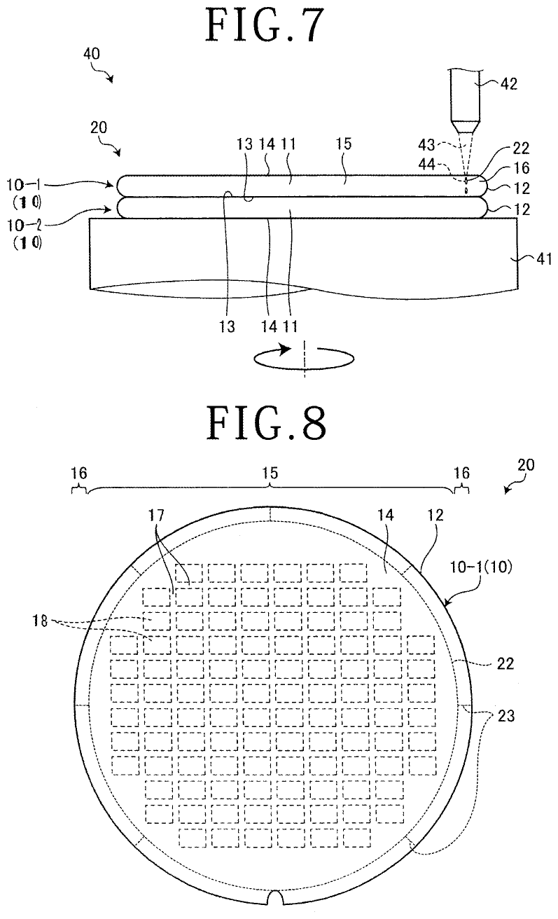

FIG. 7 is a partly cross-sectional side view illustrating how the modified layer forming step 3 illustrated in FIG. 3 is performed. FIG. 8 is a plan view illustrating the bonded wafer 20 that has undergone the modified layer forming step 3 illustrated in FIG. 3. The modified layer forming step 3 is performed after the bonded wafer forming step 2 is performed. The modified layer forming step 3 forms modified layers 22 in an annular pattern along a position on a side inner by a predetermined distance than the outer peripheral edge 12 of the first wafer 10-1. In the modified layer forming step 3, the modified layers 22 are formed inside the first wafer 10-1 through stealth dicing by a laser processing apparatus 40.

The laser processing apparatus 40 includes a holding table 41 and a laser beam applying unit 42. The holding table 41 holds the wafers 10 on a holding surface thereof and is rotatable about a vertical axis of rotation. The laser beam applying unit 42 applies a laser beam 43 to the first wafer 10-1 held on the holding table 41 via the second wafer 10-2. The laser processing apparatus 40 further includes a moving unit, which is not illustrated, for moving the holding table 41 and the laser beam applying unit 42 relative to each other and an imaging unit, which is not illustrated, for imaging the first wafer 10-1 held on the holding table 41 via the second wafer 10-2, for example.

In the modified layer forming step 3, the modified layers 22 are formed in the annular pattern by the laser beam 43 applied along the position on the side inner by the predetermined distance than the outer peripheral edge 12 of the first wafer 10-1. The position on the side inner by the predetermined distance than the outer peripheral edge 12 represents a boundary between the central region 15 and the outer peripheral region 16. The laser beam 43 is a laser beam of a wavelength having transmissivity for the first wafer 10-1 and is, for example, infrared rays (IR).

The modified layers 22 represent regions each of which has one or more of the density, refractive index, mechanical strength, and other physical properties having changed to a level or levels different from the corresponding one or ones of surrounding regions. Each modified layer 22 is, for example, a fusion treated region, a cracked region, a dielectric breakdown region, a refractive index change region, or a region where two or three of these regions exist mixed together. The modified layers 22 are lower in mechanical strength or the like than the other regions in the first wafer 10-1.

In the modified layer forming step 3, the back surface 14 of the second wafer 10-2 is first held under suction on the holding surface (upper surface) of the holding table 41. An alignment is then performed between the first wafer 10-1 and a condenser of the laser beam applying unit 42. Described specifically, the holding table 41 is moved by the moving unit, which is not illustrated, to an application region below the laser beam applying unit 42. The first wafer 10-1 is then imaged by the imaging unit, which is not illustrated, followed by an alignment to make an application portion of the laser beam applying unit 42 face, in a vertical direction, the position inner by the predetermined distance than the outer peripheral edge 12 of the first wafer 10-1, and then to set a focal point 44 of the laser beam 43 inside the first wafer 10-1.

In the modified layer forming step 3, the laser beam applying unit 42 then applies the laser beam 43 to the first wafer 10-1 from the back surface 14 thereof while the holding table 41 is rotating about the vertical axis of rotation. The laser beam 43 is thus applied in the annular pattern along the position inner by the predetermined distance than the outer peripheral edge 12 of the first wafer 10-1, so that the modified layers 22 are formed in the annular pattern.

At this time, in the modified layer forming step 3, the laser beam 43 may be applied a plurality of times to the first wafer 10-1 with a height position of the focal point 44 of the laser beam 43 changed every time in the thickness direction of the first wafer 10-1. As an alternative, the laser beam 43 may have a plurality of focal points 44 apart from one another in the thickness direction of the first wafer 10-1 and may be applied to the first wafer 10-1 such that modified layers 22 are formed in a like plurality of annular patterns overlapping in the thickness direction of the first wafer 10-1. Cracks spread from the modified layers 22, and by interconnections between the modified layers and the cracks, division start points are formed in the annular pattern at the position inner by the predetermined distance than the outer peripheral edge 12 of the first wafer 10-1.

As illustrated in FIG. 8, in the modified layer forming step 3 according to the present embodiment, additional modified layers 23 may further be formed to section the outer peripheral region 16, which is on a side of the outer peripheral edge 12 relative to the modified layers 22 in the first wafer 10-1, into at least two or more sub-regions. In the modified layer forming step 3, a plurality of, e.g., seven, additional modified layers 23 are radially formed in line patterns between an inner peripheral edge of the outer peripheral region 16 and the outer peripheral edge 12 at positions spaced at predetermined intervals in a peripheral direction in the outer peripheral region 16 of the first wafer 10-1.

In this case, the holding table 41 is moved such that the focal point 44 of the laser beam 43 moves toward a radially outer side of the first wafer 10-1. That is, by the laser beam 43 applied in the radial direction to the outer peripheral region 16, the additional modified layers 23 are formed along the radial direction. As an alternative, the laser beam 43 may be applied to the outer peripheral region 16 while the holding table 41 is moved such that the focal point 44 moves from the radially outer side toward a radially inner side of the first wafer 10-1. If this is the case, the application of the laser beam 43 is stopped upon arrival of the focal point 44 at the modified layers 22.

It is to be noted that the additional modified layers 23 illustrated in FIG. 8 section, along with a notch indicating a crystal orientation, the outer peripheral region 16 into eight sub-regions in the peripheral direction. In the present invention, however, the additional modified layers 23 may further section the outer peripheral region 16 into, for example, sixteen sub-regions, which is twice as many as the sectioning described above, in the peripheral direction, and/or may include additional modified layers 23 formed in annular patterns to section the outer peripheral region 16 into a plurality of sub-regions in the radial direction. The number of such sectioning may appropriately be set according to the diameter of the first wafer 10-1 and the width dimension of its outer peripheral region 16.

As in the formation of the modified layers 22, when forming such additional modified layers 23, the laser beam 43 may also be applied a plurality of times to the first wafer 10-1 with the height position of the focal point 44 of the laser beam 43 changed every time in the thickness direction of the first wafer 10-1. As an alternative, the laser beam 43 may have a plurality of focal points 44 apart from one another in the thickness direction of the first wafer 10-1 and may be applied to the first wafer 10-1 such that additional modified layers 23 are formed in a like plurality of annular patterns overlapping in the thickness direction of the first wafer 10-1.

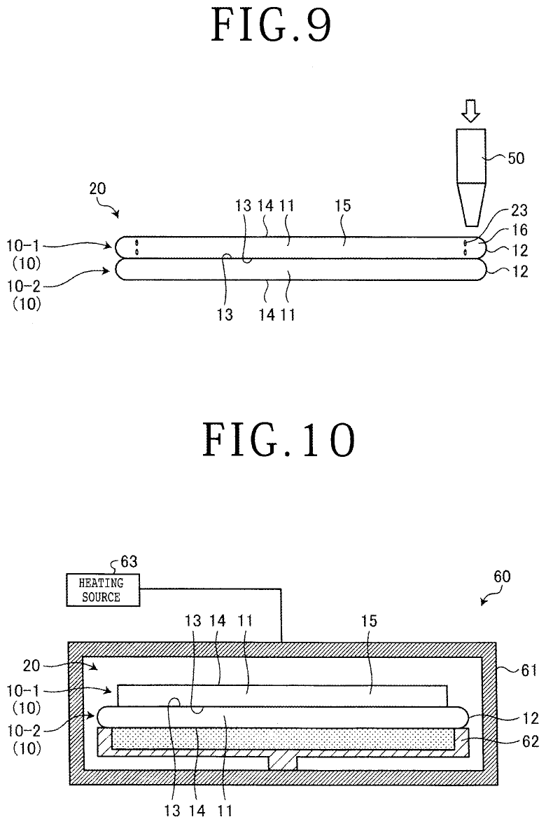

FIG. 9 is a partly cross-sectional side view illustrating an example of the outer peripheral region removal step 4 illustrated in FIG. 3. The outer peripheral region removal step 4 is performed after the modified layer forming step 3 is performed. The outer peripheral region removal step 4 applies an external force to the outer peripheral region 16 of the first wafer 10-1, the outer peripheral region 16 being on the side of the outer peripheral edge 12 relative to the position where the modified layers 22 have been formed in the annular pattern, to remove the outer peripheral region 16. In the outer peripheral region removal step 4 according to the present embodiment, the outer peripheral region 16 is removed by a shear force applied from a pressing member 50 in the thickness direction of the first wafer 10-1.

The pressing member 50 is movable in an up-down direction and applies the external force by pressing the first wafer 10-1 of the bonded wafer 20 from above and applying a downward load to the first wafer 10-1. In the outer peripheral region removal step 4, the bonded wafer 20 is first placed on a holding table, which is not illustrated, such that the first wafer 10-1 is located above. The pressing member 50 is then lowered in a state of facing the outer peripheral region 16 of the first wafer 10-1 in a vertical direction, so that the pressing member 50 is pressed against the outer peripheral region 16 of the first wafer 10-1 to apply a load.

Consequently, a downward external force is applied to the outer peripheral region 16 by the pressing member 50. Using the modified layers 22 and the cracks as start points, the central region 15 and the outer peripheral region 16 are divided, so that the outer peripheral region 16 of the first wafer 10-1 is removed.

FIG. 10 is a partly cross-sectional side view illustrating an example of the anneal processing step 5 illustrated in FIG. 3. FIG. 11 is a fragmentary cross-sectional view schematically illustrating the details of bonding between the joined surfaces in the bonded wafer 20 that has undergone the anneal processing step 5 illustrated in FIG. 3. The anneal processing step 5 is performed after the outer peripheral region removal step 4 is performed. The anneal processing step 5 increases joint strength between the first wafer 10-1 and the second wafer 10-2 by performing anneal processing on the bonded wafer 20.

The anneal processing step 5 according to the present embodiment is performed in an anneal processing system 60. The anneal processing system 60 includes a chamber 61, a holding table 62, and a heating source 63. In the chamber 61, the holding table 62 is arranged. The holding table 62 can hold the bonded wafer 20 under suction on a holding surface thereof. The chamber 61 is internally heated by the heating source 63. The heating source 63 includes, for example, infrared lamps. The holding table 62 may internally have another heating source to heat the bonded wafer 20 held on the holding surface of the holding table 62.

In the anneal processing step 5 according to the present embodiment, the bonded wafer 20 is first loaded from a loading/unloading opening, which is not illustrated, into the chamber 61 and is held on the holding table 62. The heating source 63 is then energized to heat the inside of the chamber 61. The wafers 10 in the present embodiment are Si wafers and thus easily absorb infrared rays. When heated by the heating source 63 including the infrared lamps, the bonded wafer 20 is rapidly heated. It is to be noted that such a heating method is called rapid thermal anneal (RTA).

On the bonded surfaces of the first wafer 10-1 and the second wafer 10-2 of the bonded wafer 20 thus heated, a dehydro-condensation reaction occurs. Described specifically, water (H₂O) molecules are lost from OH groups formed on the front surfaces 13, so that covalent bonds are formed via oxygen atoms (O) as illustrated in FIG. 11. This leads to an improvement in joint strength between the front surface 13 of the first wafer 10-1 and the front surface 13 of the second wafer 10-2.

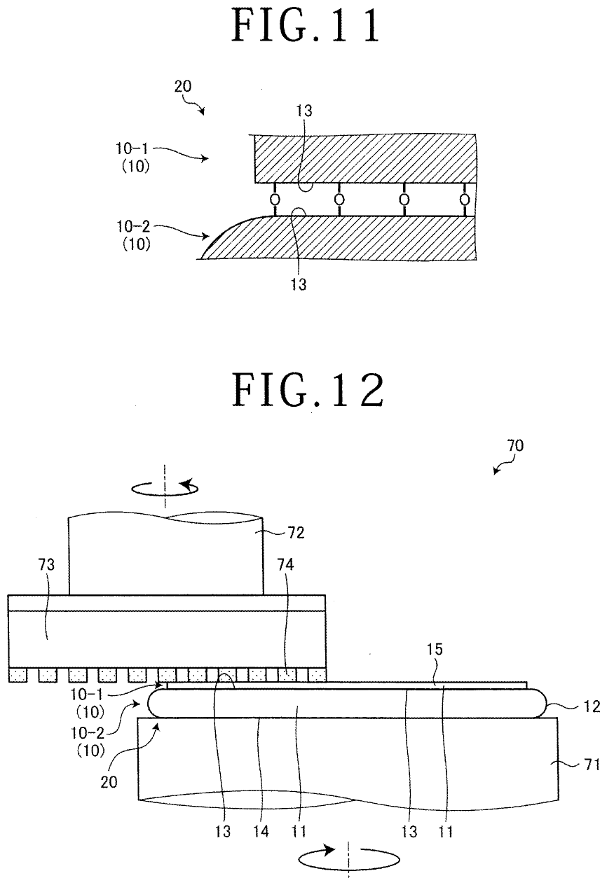

FIG. 12 is a partly cross-sectional side view illustrating how the grinding step 6 illustrated in FIG. 3 is performed. The grinding step 6 is performed after the anneal processing step 5 is performed. The grinding step 6 grinds the first wafer 10-1 of the bonded wafer 20 from the back surface 14 to thin the first wafer 10-1 to the predetermined finish thickness 21 (see FIG. 2). In other words, the first wafer 10-1 is thinned to the predetermined finish thickness 21 by being ground on the back surface 14 with a grinding apparatus 70.

The grinding apparatus 70 includes a holding table 71, a spindle 72 as a rotating shaft member, a grinding wheel 73 attached to a lower end of the spindle 72, grinding stones 74 secured to a lower surface of the grinding wheel 73, and a grinding fluid supply unit, which is not illustrated. The grinding wheel 73 rotates about an axis of rotation which is parallel to an axis of rotation of the holding table 71.

In the grinding step 6, the back surface 14 of the second wafer 10-2 is first held under suction on a holding surface of the holding table 71. With the holding table 71 rotating about its axis of ration, the grinding wheel 73 is rotated about its axis of rotation. A grinding fluid is supplied to a processing point by the grinding fluid supply unit, which is not illustrated, and at the same time, the grinding stones 74 of the grinding wheel 73 are brought closer at a predetermined feed rate toward the holding table 71, whereby the first wafer 10-1 is ground on the back surface 14 thereof by the grinding stones 74 and is thinned to the predetermined finish thickness 21 (see FIG. 2).

As described above, in the method of processing the wafer 10 according to the present embodiment, after the pair of wafers 10 is bonded to each other by a provisional joint through hydrogen bonds, the outer peripheral region 16 of the wafer 10 (first wafer 10-1) that is later to be ground to the predetermined finish thickness 21 is removed, and the joint strength is increased by anneal processing before the grinding. This makes it possible to remove the outer peripheral region 16 on the side of the outer peripheral edge 12 relative to the modified layers 22, which are formed in the annular pattern, in a state that the joint strength is weak, and hence, the outer peripheral region 16 can be removed easily and reliably compared with before.

Further, in the method of processing the wafer 10 according to the present embodiment, the step of forming the modified layers 22 in the annular pattern as division start points to remove the outer peripheral region 16 (modified layer forming step 3) is performed after the step of bonding the wafers 10 to each other (bonded wafer forming step 2). This can provide a cleaner step because processing debris produced upon the formation of the modified layers does not scatter on the bonded surfaces. In addition, a risk such as edge chipping which tends to occur upon a transfer of the wafers 10 can be suppressed because there is no need to transfer the wafers 10 to bond them together after the formation of the modified layers 22.

Moreover, cracks should not be formed to appear on both the front surface 13 and the back surface 14 of the first wafer 10-1 if the modified layers are formed in the annular pattern before the first wafer 10-1 and the second wafer 10-2 are bonded together. After the bonding, however, cracks may be formed to appear both the surfaces, so that the removal of the outer peripheral region 16 is facilitated.

### Modification

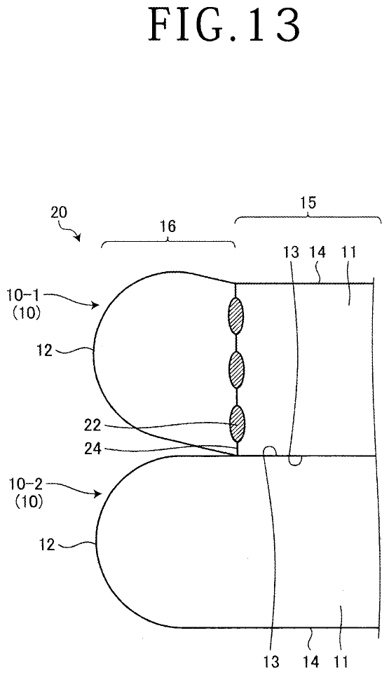

FIG. 13 is a fragmentary cross-sectional view illustrating, on an enlarged scale, a portion of a bonded wafer 20 that has undergone a modified layer forming step 3 (see FIG. 3) in a method of processing the wafer 10 according to a modification of the above-described embodiment. As illustrated in FIG. 13, cracks 24 spread from the respective modified layers 22 along a boundary between the central region 15 and the outer peripheral region 16, and the cracks 24 thus spread appear on the front surface 13 and the back surface 14 of the first wafer 10-1. It is to be noted that, in the modification, the modified layers 22 may be formed to cause cracks 24 to appear on at least the front surface 13.

In association with the formation of the modified layers 22 and the cracks 24, the first wafer 10-1 blisters at the boundary between the central region 15 and the outer peripheral region 16. As a result, the first wafer 10-1 produces a warp to protrude on the front surface 13 at the outer peripheral region 16 on the side of the outer peripheral edge 12 relative to the modified layers 22 and the cracks 24. This causes the joint, i.e., the provisional joint, between the front surface 13 of the first wafer 10-1 and the front surface 13 of the second wafer 10-2 to separate at the outer peripheral region 16. Here, the removal of the outer peripheral region 16 is easier if the cracks 24 appear on both the front surface 13 and the back surface 14 rather than appearing on the front surface 13 only.

The method of processing the wafer 10 according to the present modification is different from the method of processing the wafer 10 according to the embodiment in that the outer peripheral region removal step 4 and the anneal processing step 5 are reversed in order. Described specifically, the anneal processing step 5 is performed after the modified layer forming step 3 is performed, the outer peripheral region removal step 4 is performed after the anneal processing step 5 is performed, and the grinding step 6 is performed after the outer peripheral region removal step 4 is performed.

As the joint, i.e., the provisional joint, between the front surface 13 of the first wafer 10-1 and the front surface 13 of the second wafer 10-2 has separated at the outer peripheral region 16 in the modified layer forming step 3, the joint between the front surface 13 of the first wafer 10-1 and the front surface 13 of the second wafer 10-2 fails to provide sufficient bonding at the outer peripheral region 16 despite the occurrence of the dehydro-condensation reaction in the succeeding anneal processing step 5. In the outer periphery removal step 4 that is performed next, the outer peripheral region 16 can thus be prevented from remaining on the first wafer 10-1 due to a joint that would be formed with the second wafer 10-2 if the above-described separation did not occur.

As described above, in the method of processing the wafer 10 according to the modification, a warp is produced at the outer peripheral region 16 of the first wafer 10-1 in the modified layer forming step 3 to cause the first wafer 10-1 and the second wafer 10-2 to fail to provide sufficient bonding. The outer peripheral region 16 can hence be removed despite the anneal processing step 5 is performed before the outer peripheral region removal step 4. By performing the outer peripheral region removal step 4 after the anneal processing step 5 as described above, the bonded wafer 20 in the provisionally joined state can be prevented from moving during removal of the outer peripheral region 16 of the first wafer 10-1 or from causing air to penetrate to the joined surfaces.

It is to be noted that the present invention shall not be limited to the above-described embodiment and modification. In other words, the present invention can be practiced with various modifications within the scope not departing from the spirit of the present invention.

In the plasma activation processing step 1 according to the embodiment, in order to perform the plasma processing, the pressure in the chamber 31 is reduced to generate a plasma. However, the method of performing the plasma processing is not limited to such a vacuum plasma method as described above in the embodiment and may be, for example, an open-type atmospheric pressure plasma method of scanning the wafer 10 in its plane with a plasma generating electrode during a standby period with the wafer 10 placed on a stage.

Further, in the outer peripheral region removal step 4 according to the embodiment, the outer peripheral region 16 of the first wafer 10-1 is pressed from above to apply the external force in a shear direction. However, the method of applying the external force is not limited to the above-described method, and may be a method of applying the external force in the shear direction by lifting up the outer peripheral region 16 of the first wafer 10-1 or a method of crushing the outer peripheral region 16 of the first wafer 10-1 between rollers. Without being limited to a mechanical external force, the external force may also be vibrations generated by ultrasonic waves or an external force generated in a radial direction by expanding an expandable tape bonded to the back surface 14 of the first wafer 10-1.

Moreover, in the anneal processing step 5 according to the embodiment, single wafer RTA is performed to rapidly heat a plurality of bonded wafers 20 one after one in the chamber 61. However, the method of performing the anneal processing on the bonded wafer 20 is not limited to the above-described method and may be a batch-type anneal processing method of concurrently performing a heat treatment on a plurality of bonded wafers 20 arranged, for example, in a quartz furnace tube, by heating them from outside. In addition, the anneal processing method is not limited to a method of heating the bonded wafer 20 by infrared rays and may be a method of heating the bonded wafer 20 on a hot plate.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer, comprising:
a plasma activation processing step of performing plasma processing on at least either one surface of a first wafer or one surface of a second wafer and thus activating the at least one surface that has been subjected to the plasma processing, to thereby join the first wafer and the second wafer;
a bonded wafer forming step of, after performing the plasma activation processing step, forming a bonded wafer by provisionally joining the one surface of the first wafer and the one surface of the second wafer;
a modified layer forming step of, after performing the bonded wafer forming step, forming modified layers in an annular pattern inside the first wafer by applying a laser beam of a wavelength having transmissivity for the first wafer, in the annular pattern to the first wafer along a position on a side inner by a predetermined distance than an outer peripheral edge of the first wafer;
an outer peripheral region removal step of, after performing the modified layer forming step, removing an outer peripheral region of the first wafer, the outer peripheral region being on a side of the outer peripheral edge relative to the position where the modified layers have been formed in the annular pattern, by applying an external force to the outer peripheral region;
an anneal processing step of, after performing the outer peripheral region removal step, performing anneal processing on the bonded wafer to increase joint strength between the first wafer and the second wafer; and
a grinding step of, after performing the anneal processing step, grinding the first wafer of the bonded wafer from another surface of the first wafer to thin the first wafer to a predetermined finish thickness.

2. The method of processing a wafer according to claim 1, wherein,
in the modified layer forming step, the laser beam is applied a plurality of times to the first wafer with a height position of a focal point of the laser beam changed every time in a thickness direction of the first wafer, such that modified layers are formed in a like plurality of annular patterns overlapping in the thickness direction of the first wafer.

3. The method of processing a wafer according to claim 1, wherein,
in the modified layer forming step, a laser beam having a plurality of focal points apart from one another in a thickness direction of the first wafer is applied to the first wafer such that modified layers are formed in a like plurality of annular patterns overlapping in the thickness direction of the first wafer.

4. A method of processing a wafer, comprising:
a plasma activation processing step of performing plasma processing on at least either one surface of a first wafer or one surface of a second wafer and thus activating the at least one surface that has been subjected to the plasma processing, to thereby join the first wafer and the second wafer;
a bonded wafer forming step of, after performing the plasma activation processing step, forming a bonded wafer by provisionally joining the one surface of the first wafer and the one surface of the second wafer;
a modified layer forming step of, after performing the bonded wafer forming step, forming modified layers in an annular pattern inside the first wafer and also forming cracks in such a manner as to spread from the modified layers and appear on the one surface of the first wafer, by applying a laser beam of a wavelength having transmissivity for the first wafer, in the annular pattern to the first wafer along a position on a side inner by a predetermined distance than an outer peripheral edge of the first wafer;
an anneal processing step of, after performing the modified layer forming step, performing anneal processing on the bonded wafer to increase joint strength between the first wafer and the second wafer;
an outer peripheral region removal step of, after performing the anneal processing step, removing an outer peripheral region of the first wafer, the outer peripheral region being on a side of the outer peripheral edge relative to the position where the modified layers have been formed in the annular pattern, by applying an external force to the outer peripheral region; and
a grinding step of, after performing the outer peripheral region removal step, grinding the first wafer of the bonded wafer from another surface of the first wafer to thin the first wafer to a predetermined finish thickness.

5. The method of processing a wafer according to claim 4, wherein,
in the modified layer forming step, the laser beam is applied a plurality of times to the first wafer with a height position of a focal point of the laser beam changed every time in a thickness direction of the first wafer, such that modified layers are formed in a like plurality of annular patterns overlapping in the thickness direction of the first wafer.

6. The method of processing a wafer according to claim 4, wherein,
in the modified layer forming step, a laser beam having a plurality of focal points apart from one another in a thickness direction of the first wafer is applied to the first wafer such that modified layers are formed in a like plurality of annular patterns overlapping in the thickness direction of the first wafer.
